(19) United States
(12) Patent Application Publication
(10) Pub. No.: US 2009/0288699 A1
(43) Pub. Date: Nov. 26, 2009

(54) LAMINATE STRUCTURES FOR HIGH TEMPERATURE PHOTOVOLTAIC APPLICATIONS, AND METHODS RELATING THERETO

(75) Inventors: Brian C. Auman, Pickerington, OH (US); Salah Boussaad, Wilmington, DE (US); Thomas Edward Carney, Orient, OH (US); Kuppusamy Kanakarajan, Dublin, OH (US); Kostantinos Kourtakis, Media, PA (US); John W. Simmons, Wilmington, DE (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E.I. DU PONT DE NEMOURS AND COMPANY, Wilmington, DE (US)

(21) Appl. No.: 12/466,033

(22) Filed: May 14, 2009

Related U.S. Application Data
(60) Provisional application No. 61/054,505, filed on May 20, 2008.

(51) Int. Cl. H01L 31/042; H01L 31/00

(52) U.S. Cl. 136/249; 136/256

(57) ABSTRACT

Laminate structures are disclosed, comprising a metal foil supporting a polyimide dielectric layer. The polyimide dielectric layer comprises a polyimide derived from at least one aromatic rigid rod diamine and at least one aromatic rigid rod dianhydride to provide a thermally and dimensionally stable polyimide. A bottom electrode is formed directly on the polyimide dielectric layer surface, and a CIGS absorber layer is formed directly on the bottom electrode. The CIGS laminates of the present disclosure can be incorporated into CIGS type solar cells, and the laminates further allow such CIGS solar cells to be monolithically integrated into a photovoltaic module on a single substrate.

### FIELD OF DISCLOSURE

This disclosure relates generally to thermally and dimensionally stable polyimide-on-metal laminates for high temperature photovoltaic applications. More specifically, the laminates of the present invention enable monolithic integration of CIGS type photovoltaic cells.

### BACKGROUND OF THE DISCLOSURE

Photovoltaic devices, e.g., solar cells, are capable of converting solar radiation into usable electrical energy. One type of solar cell involves the use of copper indium gallium di-selenide (“CIGS”). In the manufacture of CIGS solar cells, CIGS deposition technology generally requires very high processing temperatures, generally above 450° C., for higher photovoltaic efficiency. Glass and metal have been used as substrates for CIGS photovoltaic cells, due to their thermal and dimensional stability at high temperatures. However, glass lacks flexibility and can be heavy, bulky and subject to breakage. Metal has advantages over glass, but the inherent electrical conductivity of metal generally precludes monolithic integration of CIGS solar cells. While polyimides are known for high temperature stability, conventional polyimides generally cannot provide sufficient thermal and dimensional stability at desired CIGS processing temperatures.

A need therefore exists for CIGS substrates that: i. have sufficient thermal and dimensional stability to withstand fabrication temperatures in the production of high efficiency CIGS based photovoltaic devices; and ii. have sufficient electrical insulation properties to allow monolithic integration of CIGS solar cells.

### SUMMARY

The present disclosure is directed to CIGS laminate structures comprising a metal foil having a thickness from 5 to 100 microns, where the metal foil supports a polyimide dielectric layer having a thickness from 8 to 100 microns. The polyimide dielectric layer is in direct contact with the metal foil and comprises a polyimide derived from at least one aromatic rigid rod diamine and at least one aromatic rigid rod dianhydride to provide a polyimide having a glass transition temperature (“Tg”) greater than 300° C. and a polyimide dielectric layer having an isothermal weight loss of less than 1% at 500° C. over 30 minutes (in an inert atmosphere, such as a vacuum or under nitrogen or other inert gas) and an in-plane CTE less than 25 ppm/° C. A bottom electrode is formed directly on the polyimide dielectric layer surface, so the polyimide dielectric layer is positioned between the metal foil and the bottom electrode. A CIGS layer is formed directly on the bottom electrode, so the bottom electrode is positioned between the CIGS layer and the polyimide dielectric layer. The CIGS laminates of the present disclosure can be incorporated into CIGS type solar cells, and the laminates further allow such CIGS solar cells to be monolithically integrated into a photovoltaic module on a single substrate.

### BRIEF DESCRIPTION OF THE DRAWING

The accompanying drawing, which is incorporated in and forms a part of the specification, illustrates the preferred embodiment of the present invention, and together with the descriptions serve to explain the principles of the invention.

### In the Drawing:

The FIGURE is a sectional view of a thin-film solar cell comprising a laminate in accordance with the present invention.

### DETAILED DESCRIPTION OF THE PREFERRED EMBODIMENTS

The term “laminate” herein denotes a material constructed by uniting two or more layers of materials together. In one embodiment, the laminate comprises at least one metal layer and at least one dielectric layer.

The term “film” herein denotes a free standing film or a coating on a substrate. The term “film” is used interchangeably with the term “layer” and refers to covering a desired area.

The term “monolithic integration” herein denotes a plurality of photovoltaic cells being fabricated on the same substrate, where the cells are integrated or otherwise interconnected to form a module.

The term “metal foil” herein denotes any metal foil thermally and dimensionally stable above 450° C.

The terms “CIGS layer” and “CIGS laminate” are intended to mean layers or laminates (as the case may be) comprising an absorber layer comprising: i. a copper indium gallium di-selenide composition; ii. a copper indium gallium disulfide composition; iii. a copper indium di-selenide composition; iv. a copper indium disulfide composition; or v. any element or combination of elements that could be substituted for copper, indium, gallium, di-selenide, and/or disulfide, whether presently known or developed in the future.

“Dianhydride” as used herein is intended to include precursors or derivatives thereof, which may not technically be a dianhydride but would nevertheless react with a diamine to form a polyamic acid which could in turn be converted into a polyimide. Similarly, “diamine” as used herein is intended to include precursors or derivatives thereof, which may not technically be a diamine but would nevertheless react with a dianhydride to form a polyamic acid which could in turn be converted into a polyimide.

The present disclosure is directed to a laminate comprising a high performance polyimide dielectric layer directly supported by a metal foil. In one embodiment, the laminate also includes a flexible CIGS photovoltaic cell bottom electrode formed directly on the polyimide dielectric layer, whereby the polyimide dielectric layer is positioned between the metal foil and the bottom electrode. In a further embodiment a CIGS layer is formed over the bottom electrode, whereby the bottom electrode is between the CIGS layer and the polyimide dielectric layer. The polyimide dielectric layer provides excellent electrical insulation properties (as well as sufficient thermal and dimensional stability at CIGS processing temperatures), allowing monolithic integration of CIGS type solar cells built thereon. In one embodiment, one or more layers are built upon the polyimide layer by a reel-to-reel process to produce CIGS photovoltaic modules or a multilayer precursor thereto.

The laminates of the present disclosure comprise a metal foil. The metal foil provides thermal and dimensional support for the polyimide dielectric layer, particularly when the polyimide dielectric layer is subjected to high CIGS processing temperatures, typically greater than 400° C. (the efficiency of CIGS photovoltaic cells generally increases with higher processing temperatures, oftentimes greater than 450° C.). The metal foil should be as thin as possible so as not to add excessive weight to the photovoltaic module but thick enough to supply necessary support for the polyimide dielectric layer, depending upon the processing temperature chosen for any particular application of the present invention. The weight of the photovoltaic module can become particularly important for space and near space applications. In some embodiments, the metal foil is a stainless steel foil. In other embodiments, the foil comprises or consists of titanium. In other embodiments, the foil can be of virtually any metal having thermal and dimensional stability above 450° C. In some embodiments, the metal foil has a thickness between (and optionally including) any two of the following thicknesses: 5, 6, 7, 8, 9, 10, 20, 30, 40, 50, 60, 70, 80, 90 and 100 microns.

The laminates of the present disclosure comprises a polyimide dielectric layer. In one embodiment, the polyimide dielectric layer is located between a bottom CIGS electrode and the metal foil. The polyimide dielectric layer provides electrical insulation, so CIGS type photovoltaic cells built thereon can be monolithically integrated into a photovoltaic module.

It is desirable for the polyimide of the present disclosure to have an in-plane or linear coefficient of thermal expansion (CTE) that closely matches the CTE of the metal foil, the bottom electrode and the other CIGS layers to avoid cracking of the thin layers due to thermal expansion mismatch of the layers. The in-plane or linear coefficient of thermal expansion (CTE) of the polyimide film of the present disclosure can be obtained by thermomechanical analysis utilizing a TA Instruments TMA-2940 run at 10° C./min, up to 380° C., then cooled and reheated to 380° C., with the CTE in ppm/° C. obtained during the reheat scan between 50° C. and 350° C.

A polyimide CTE that closely matches the metal foil and the CIGS layers will also minimize undesirable curling of the layers. The polyimide can be tailored to provide the desired CTE. This can be accomplished by the proper selection of monomers, addition of fillers, imidization process and any combination thereof, using ordinary skill and experimentation, depending upon the particular application chosen. Generally, when forming the polyimide, a chemical conversion process (as opposed to a thermal conversion process) will provide a lower CTE polyimide film; chemical conversion processes for converting polyamic acid into polyimide are well known and need not be further described here. Generally, polyimides with highly rigid rod-like backbone structures give low in-plane CTE. The CTE can be tailored by the proper balance of rigid rod-like and flexible monomers in the polymer backbone.

The thickness of the polyimide dielectric layer can also impact CTE with thinner films tending to give a lower CTE. In one embodiment, the polyimide dielectric layer has an in-plane CTE less than 25 ppm/° C. In another embodiment, the polyimide dielectric layer has an in-plane CTE less than 20 ppm/° C. In yet another embodiment, the polyimide dielectric layer has an in-plane CTE less than 10 ppm/° C. In some embodiments, the in-plane CTE is between (and optionally including) any two of the following: 1, 5, 10, 15, 20, and 25 ppm/° C. Ordinary skill and experimentation may be necessary in fine tuning the CTE of the polyimide dielectric layer, depending upon the polyimide composition chosen in accordance with the present disclosure.

It is also desirable for the polyimide of the present disclosure to have a high glass transition temperature (Tg). A high Tg helps maintain mechanical properties, such as storage modulus, at high temperatures. Above the glass transition temperature (Tg), the polymer can soften and lose mechanical strength and integrity, making it difficult to process in a continuous roll to roll fashion without deformation and wrinkling. In some embodiments, the polyimide has a Tg greater than 300° C. In another embodiment, the polyimide has a Tg greater than 350° C. In yet another embodiment, the polyimide has a Tg greater than 370° C. In some embodiments, the polyimide has a Tg above (and optionally including) any of the following: 300, 310, 320, 330, 340, 350, 360, 370, 380, 390 or 400° C.

In some embodiments, the polyimide dielectric layer comprises a filler. The addition of filler increases the storage modulus, particularly above the Tg of the polyimide, producing a more dimensionally stable polyimide capable of handling the high temperatures associated with CIGS processing. In some embodiments, the filler is selected from the group consisting of spherical or near spherical shaped fillers, platelet-shaped fillers, needle-like fillers, fibrous fillers and mixtures thereof. In some embodiments, the platelet-shaped fillers and needle-like fillers and fibrous fillers will maintain or lower the CTE of the polyimide layer while still increasing the storage modulus. Useful fillers should be stable at CIGS processing temperatures and not substantially decrease the electrical insulation of the polyimide film. In some embodiments, the filler is selected from the group consisting of mica, talc, boron nitride, wollastonite, clays, calcinated clays, silica, alumina, platelet alumina, glass flake, glass fiber and mixtures thereof. The fillers may be treated or untreated.

In some embodiments, the filler is selected from a group consisting of oxides (e.g., oxides comprising silicon, titanium, magnesium and/or aluminum), nitrides (e.g., nitrides comprising boron and/or silicon) or carbides (e.g., carbides comprising tungsten and/or silicon). In some embodiments, the filler comprises oxygen and at least one member of the group consisting of aluminum, silicon, titanium, magnesium and combinations thereof. In some embodiments, the filler comprises platelet talc, acicular titanium dioxide, and/or acicular titanium dioxide, at least a portion of which is coated with an aluminum oxide. In some embodiments the filler is less than 50, 25, 20, 15, 12, 10, 8, 6, 5, 4, 2, 1, 0.8, 0.75, 0.65, 0.5, 0.4, 0.3, or 0.25 microns in all dimensions.

In another embodiment, low amounts of carbon fiber and graphite may be used. In yet another embodiment, low amounts of carbon fiber and graphite may be used in combination with other fillers. In some embodiments, the filler is coated with (or the polyimide otherwise comprises) a coupling agent. In some embodiments, the filler is coated with (or the polyimide otherwise comprises) an aminosilane coupling agent. In some embodiments, the filler is coated with (or the polyimide otherwise comprises) a dispersant. In some embodiments, this filler is coated with (or the polyimide otherwise comprises) a combination of a coupling agent and a dispersant. Depending on the particular filler used, too low a filler loading may have minimal impact on the film properties, while too high a filler loading may cause the polyimide to become brittle. Ordinary skill and experimentation may be necessary in selecting any particular filler in accordance with the present disclosure, depending upon the particular application selected. In some embodiments, the filler is present in an amount between (and optionally including) any two of the following weight percentages: 5, 10, 15, 10, 25, 30, 35, 40, 45, 50, 55, 60, 65 and 70 weight percent of the total weight of the polyimide dielectric layer.

In some embodiments, suitable fillers are generally stable at temperatures above 450° C., and in some embodiments do not significantly decrease the electrical insulation properties of the film. In some embodiments, the filler is selected from a group consisting of needle-like fillers, fibrous fillers, platelet fillers and mixtures thereof. In one embodiment the filler is spherical or near spherical. In one embodiment, the fillers of the present disclosure exhibit an aspect ratio of at least 3, 4, 5, 6, 7, 8, 9, 10, 11, 12, 13, 14, or 15 to 1. In one embodiment, the filler aspect ratio is 6:1. In another embodiment, the filler aspect ratio is 10:1, and in another embodiment, the aspect ratio is 12:1.

In some embodiments, the filler comprises materials derived from nanoparticles of silicon oxide, aluminum oxide, titanium oxide, niobium oxide, tantalum oxide and their mixtures to promote compatibilization with the metal foil substrate. In some embodiments, the average diameter of these nanoparticles can be 200 nm or less and can encompass aspect ratios ranging from one (spherical particles) to higher aspect ratios (oblong spheres, nanoneedles). The nanoparticles can encompass 1-30 wt % of the total weight of the polyimide layer and can be added optionally with dispersant or silane type coupling agents and can be combined with other fillers to produce the final polyimide dielectric layer.

In some embodiments, there is a practical limit to the filler particle size. If the filler size is too large, then desired surface smoothness may not be obtained. If the filler is too small, agglomeration may occur and good dispersion may not be achieved, which can result in low dielectric strength. Therefore when selecting the size of filler, the balance between desired surface roughness of the film, filler dispersability and processibility should be considered. In some embodiments, the polyimide layer comprises a nanofiller. The term nanofiller is intended to mean a filler with at least one dimension less than 1000 nm, i.e., less than 1 micron. In some embodiments, special dispersion techniques may be necessary when nanofillers are used as they can be more difficult to disperse. In some embodiments the filler has at least one dimension that (on average) is less than 1000, 800, 600, 500, 450, 400, 350, 300, 275, 250, 225 or 200 nanometers (nm).

Surface roughness is another important feature of the polyimide dielectric layer. Surface roughness as provided herein can be determined by optical surface profilometry to provide Ra values, such as, by measuring on a Veeco Wyco NT 1000 Series instrument in VSI mode at 25.4x or 51.2x utilizing Wyco Vision 32 software. The bottom electrode, typically comprises, but is not limited to, molybenum, that sits on top of the polyimide dielectric layer. The bottom electrode is typically very thin (about 5 microns, for example) as are the other layers that make up a CIGS photovoltaic cell (a few microns or nanometers, for example, depending on the particular layer). Any unevenness, roughness, defects or asperities on the surface of the metal foil or the polyimide dielectric layer can potentially cause a short or defect though the layers, particularly between the electrodes of the CIGS solar cell.

Metal foils have surface irregularities such as grooves, peaks and cavities as a result of the foil production. In one embodiment, the polyimide dielectric layer on top of the metal foil forms a smoother surface compared to the metal foil alone. In some embodiments, surface roughness of the polyimide dielectric layer (with respect to the surface to be bonded to the bottom electrode) is less than 500 nm. In another embodiment, surface roughness of the polyimide layer is less than 200 nm. In yet another embodiment, surface roughness of the polyimide layer is less than 100 nm. In some embodiments, the surface roughness is between (and optionally including) any two of the following numbers: 50, 75, 100, 150, 200, 250, 300, 350, 400, 450 and 500 nm.

In some embodiments, the crystallinity, and amount of crosslinking of the polyimide film can aid in storage modulus retention. In another embodiment, the polyimide layer comprises a thermally stable reinforcing fabric, paper, sheet, scrim and combinations thereof in order to increase the storage modulus of the polyimide. In one embodiment, the storage modulus (DMA) at 480° C. is greater than (and optionally equal to) any of the following numbers: 190, 200, 250, 300, 350, 400, 450, 500, 550, 600, 650, 700, 750, 800, 850, 900, 950, 1000, 1100, 1200, 1300, 1400 or 1500.

The polyimide films of the present disclosure should have high thermal stability so that they do not substantially degrade, lose weight and exhibit diminished mechanical properties, as well as, do not give off significant volatiles during the deposition process. In some embodiments, the polyimide layer has an isothermal weight loss of less than 1% at 500° C. over 30 minutes under inert conditions, such as in a substantial vacuum, in a nitrogen or any inert gas environment.

The polyimide dielectric layer of the present disclosure should be thin so as to not add excessive weight to the photovoltaic module but thick enough to provide high electrical insulation at operating voltages which is some cases may reach 1000V. In some embodiments, the polyimide dielectric layer has a thickness between (and optionally including) any two of the following thicknesses 8, 10, 20, 30, 40, 50, 60, 70, 80, 90 and 100 microns.

Polyimide dielectric layer of the present disclosure have high dielectric strength. In some embodiments, the dielectric strength of the polyimide dielectric layer is much higher compared to common inorganic insulators. In some embodiments, polyimide dielectric layer of the present disclosure has a dielectric strength greater than 39.4 KV/mm. In some embodiments, polyimide dielectric layers of the present disclosure have a dielectric strength greater than 213 KV/mm.

It is important that the polyimide layer be as free as possible of pinhole or other defects (foreign particles, conductive particles, gels, filler agglomerates and other contaminates) that could adversely impact the electrical integrity and dielectric strength of the polyimide layer. The term “pinhole” as used herein includes any small holes that result from non-uniformities in a layer or otherwise arising from the manufacturing process.

Defects (i.e., layer non-uniformities) can be a serious issue, particularly in photovoltaic thin films, where electrical performance can be highly dependant upon layer uniformity. The polyimide dielectric layer can be made thicker in an attempt to decrease defects or their impact on the layer's integrity or alternatively, multiple polyimide dielectric layers may be used. Thin multiple polyimide layers can be advantageous over a single polyimide layer of the same thickness. Such polyimide multilayers can greatly eliminate the occurrence of through-film pinholes or defects, because the likelihood of defects that overlap in each of the individual layers is extremely small and therefore a defect in any one of the layers is much less likely to cause an electrical failure through the entire thickness of the polyimide dielectric layer. In some embodiments, the polyimide dielectric layer comprises two or more layers of polyimide. In some embodiments, the polyimides layers may be the same. In some embodiments, the polyimide layers may be different. In some embodiments, the polyimide layers independently may comprise a thermally stable filler, reinforcing fabric, inorganic (e.g., mica) paper, sheet, scrim and/or combinations thereof.

Useful polyimides of the present disclosure are derived from at least one aromatic rigid rod diamine and at least one aromatic rigid rod dianhydride. Suitable aromatic rigid rod diamine monomers include: 1,4-diaminobenzene (PPD), 4,4′-diaminobiphenyl, 2,2′-bis(trifluoromethyl)benzidene (TFMB), 1,4-naphthalenediamine, and/or 1,5-naphthalenediamine. Suitable aromatic rigid rod dianhydride monomers include pyromellitic dianhydride (PMDA), and/or 3,3′,4,4′-biphenyl tetracarboxylic dianhydride (BPDA). In one embodiment, the polyimide of the polyimide dielectric layer is derived from 1,4-diaminobenzene (PPD), and 3,3′,4,4′-biphenyl tetracarboxylic dianhydride (BPDA). In another embodiment, the polyimide of the polyimide dielectric layer is derived from 3,3′,4,4′-biphenyl tetracarboxylic dianhydride (BPDA), and a combination of 1,4-diaminobenzene (PPD) and 1,5-naphthalenediamine where over 50 mole percent of the diamine is 1,5-naphthalenediamine.

In some embodiments in addition to the aromatic rigid rod diamine, a non rigid rod aromatic diamine is selected, such as for example, from a group consisting of 3,4′-diaminodiphenyl ether (3,4′-ODA), 4,4′-diaminodiphenyl ether (4,4′-ODA), 1,3-diaminobenzene (MPD), 4,4′-diaminodiphenyl sulfide, 9,9′-bis(4-amino)fluorene, and the like and mixtures thereof. Generally speaking 50, 60, 70, 75, 80, 85, 90, 95, 97, 98, 99 or 100% of the aromatic diamine is rigid rod, since the non rigid rod aromatic diamine are generally less effective in providing high temperature thermal and dimensional stability, but the non rigid rod aromatic diamines may be useful nevertheless in fine tuning other polyimide properties, such as CTE, particularly in applications where thermal and dimensional stability are less critical. Ordinary skill and experimentation may be necessary in selecting any particular aromatic diamine in accordance with the present disclosure.

In some embodiments, in addition to the aromatic rigid rod dianhydride, a non rigid rod aromatic dianhydride is selected, such as for example, from a group consisting 3,3′,4,4′-benzophenone tetracarboxylic dianhydride (BTDA); 4,4′-oxydiphthalic anhydride (ODPA), 3,3′,4,4′-diphenyl sulfone tetracarboxylic dianhydride (DSDA), 2,2-bis(3,4-dicarboxyphenyl)hexafluoropropane dianhydride (6FDA), and the like and mixtures thereof. Generally speaking 50, 60, 70, 75, 80, 85, 90, 95, 97, 98, 99 or 100% of the aromatic dianhydride is rigid rod, since the non rigid rod aromatic dianhydrides are generally less effective in providing high temperature thermal and dimensional stability, but the non rigid rod aromatic dianhydrides may be useful nevertheless in fine tuning other polyimide properties, such as CTE, particularly in applications where thermal and dimensional stability are less critical. Ordinary skill and experimentation may be necessary in selecting any particular aromatic diamine in accordance with the present disclosure.

Polyimides of the present disclosure can be made by methods well known in the art and their preparation need not be discussed here. In some embodiments, the polyimide layer is cast onto a metal foil in the form of a polyamic acid, dried and cured to form a polyimide. In some embodiments, the polyimide and metal foil have reliable adhesion or bonding to one another. In some embodiments bonding between the metal foil and polyimide dielectric layer is created or enhanced during a heating cycle, such as, after the CIGS layer is deposited and subjected to annealing. In one embodiment, the bottom electrode is directly deposited onto the polyimide dielectric layer surface opposite that of the metal foil by any conventional or nonconventional method (typically, but not limited to, sputtering or vapor deposition). In one embodiment, CIGS photovoltaic type or related layers can be sequentially deposited over the bottom electrode by conventional methods, well known or described in the art. In one embodiment, a top transparent electrode (typically, but not limited to, indium tin oxide or zinc oxide) is deposited on top of the CIGS layer.

Such additional layers (in addition to the metal foil, polyimide dielectric layer, bottom electrode and CIGS layer) may or may not be part of the laminate structure of the present disclosure, depending upon whether finished CIGS photovoltaic modules are desired or whether a precursor thereof is desired (for example, where the precursor is sold to another for further processing and completion of the CIGS photovoltaic module(s)). An advantage of the laminate structures of the present disclosure is that they are well adapted to reel-to-reel processing, so rolls can be fabricated, either as a finished CIGS photovoltaic product or as a precursor thereto, where a precursor roll can be sent to another manufacturing operation and further processed by further reel-to-reel manufacturing processes.

The combination of the metal foil and the polyimide dielectric layer provides a support structure that can be processed at temperatures above 400, 425 or 450° C. in reel-to-reel operations, due to the mechanical support provided by the metal foil to the polyimide dielectric layer. The polyimide dielectric layer in turn allows for CIGS solar cells to be monolithically integrated, due to the electrical insulation properties of the polyimide dielectric layer.

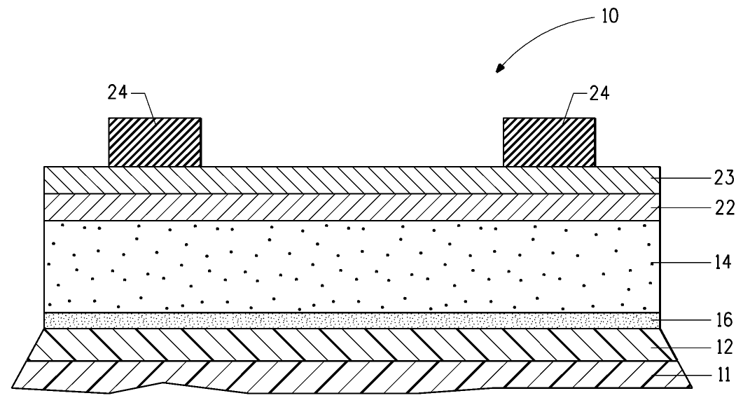

Referring now to FIG. 1, an embodiment of the present disclosure is illustrated as a thin-film solar cell, indicated generally at 10. The solar cell 10 comprises a polyimide dielectric layer 12 supported by metal substrate 11. In the manufacture of the solar cell 10, the polyimide dielectric layer 12 can be first applied onto the metal substrate 11 and this two layer laminate can them be incorporated into the solar cell 10 by forming a bottom electrode 16 onto the polyimide dielectric layer 12 and then forming the CIGS (semiconductor absorber) layer 14 over the bottom electrode 16.

In one embodiment of the present disclosure, the CIGS layer 14 is a deposition of high quality Cu(In, Ga)Se₂ (CIGS). Processes for the deposition of the CIGS layer 14 are well known (see for example, U.S. Pat. No. 5,436,204 and U.S. Pat. No. 5,441,897) and need not be described further here. It should be noted that the deposition of the CIGS layer 14 onto the bottom electrode 16 can be by any of a variety of conventional or non-conventional techniques including, but limited to, sputtering, vapor evaporation/deposition, printing, and the like.

To complete the construction of the thin-film solar cell 10, the CIGS layer 14 can be paired with a II/VI film 22 to form a photoactive heterojunction. In some embodiments, the II/VI film 22 is constructed from cadmium sulfide (CdS). Constructing the II/VI film 22 from other materials including, but not limited to, cadmium zinc sulfide (CdZnS) and/or zinc selenide (ZnSe) is also within the scope of the present disclosure.

A transparent conducting oxide (TCO) layer 23 for collection of current can be applied to the II/VI film. In one embodiment, the transparent conducting oxide layer 23 is constructed from zinc oxide (ZnO) or indium tin oxide (ITO), although constructing the transparent conducting oxide layer 23 from other materials is also within the scope of the present disclosure.

A suitable grid contact 24 or other suitable collector can be deposited on the upper surface of the TCO layer 23 when forming a stand-alone thin-film solar cell 10. The grid contact 24 can be formed from various materials but should have high electrical conductivity and form a good ohmic contact with the underlying TCO layer 23. In some embodiments, the grid contact 24 is constructed from a metal material. In some embodiments, the grid contact 24 can be constructed from materials including, but not limited to, aluminum, indium, chromium, or molybdenum, with an additional conductive metal overlayment, such as copper, silver, or nickel is within the scope of the present disclosure.

Also, one or more anti-reflective coatings (not shown) can be applied to the grid contact 24 to improve the collection of incident light by the thin-polyimide dielectric layer solar cell 10. As understood by a person skilled in the art, any suitable anti-reflective coating is within the scope of the present disclosure.

As used herein, the terms “comprises,” “comprising,” “includes,” “including,” “has,” “having” or any other variation thereof, are intended to cover a non-exclusive inclusion. For example, a method, process, article, or apparatus that comprises a list of elements is not necessarily limited only those elements but may include other elements not expressly listed or inherent to such method, process, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of the “a” or “an” are employed to describe elements and components of the invention. This is done merely for convenience and to give a general sense of the invention. This description should be read to include one or at least one and the singular also includes the plural unless it is obvious that it is meant otherwise.

### EXAMPLES

The invention will be further described in the following examples, which do not limit the scope of the invention described in the claims.

Examples 1 to 14 illustrate how some of the properties (particularly storage modulus) of a polyimide layer can be improved by the addition of a filler.

### Example 1

A random polyamic acid copolymer of BPDA/PMDA//PPD/4,4′ODA of about a 95/5//92/8 molar ratio was prepared by standard methods in DMAC at about 15% solids with a slight excess of amine to a viscosity of about 50-100 poise (hereafter referred to as “prepolymer”). To this prepolymer solution, a freshly prepared solution of 6 wt % PMDA in DMAC was added in small portions incrementally to increase the molecular weight of the polymer and give a viscosity of about 500 poise as measured on a Brookfield DV-II+ viscometer at 20 rpm with a #5 spindle (hereafter referred to as “finished polymer”). The finished polymer solution was cast onto a heated glass plate and dried at about 80° C. to a tack free coating that was then carefully removed from the glass surface to yield a DMAC-containing free-standing film. This film was placed on a pin frame and placed in an oven at 120° C. for 30 minutes. Afterwards, the oven temperature was ramped to 320° C. over about 20 minutes and held at 320° C. for 30 minutes. The pin frame was removed from the oven and placed in a separate oven preheated to 400° C. for about 5 minutes. The pin frame was removed from this oven and the cured film was released from the pin frame.

### Example 2

A slurry of HR-2 mica from Kish Company (Mentor, Ohio, USA) was prepared by dispersing about 70 g in 116.2 g of DMAC utilizing a Silverson high shear mixer. After the mica was thoroughly wetted out by the solvent, a small portion (13.8 g) of the prepolymer from Example 1 was added and the slurry was allowed to further mix for about 30 min. A portion of this slurry (17.7 grams) was added to a larger portion of the prepolymer from Example 1 (179.6 g) and this mixture was stirred for about 1 hour using a high torque mixer. To this prepolymer/filler mixture, small portions of PMDA in DMAC were added incrementally in order to increase the polymer molecular weight and bring the viscosity of the mixture to about 500 poise (Brookfield, ref. Example 1). This finished polymer/mica mixture was cast into a film and cured in a similar manner to that described in Example 1 to yield a filled polyimide film containing about 20 wt % mica.

### Example 3

In a similar manner to Example 2, a second portion (41.5 g) of the slurry described in Example 2 was added to a 156.2 g portion of the prepolymer from Example 1. This prepolymer/mica mixture was finished, cast and cured in a manner similar to that described in Examples 1 and 2 to yield a filled polyimide film containing about 40 wt % mica.

### Examples 4-14

In a similar manner to Examples 2, other fillers were employed to produce filled polyimide films containing various percentages of the chosen fillers. These are listed below in Table 1.

TABLE 1

| | | Filler Loading in |
|---|---|---|
| | | Polyimide Film (in |
| Example # | Filler | weight percent) |
| 4 | HR-2 coated with | 20 |
| | aminosilane (Kish Co.) | |
| 5 | HR-2 coated | 40 |
| 6 | HR-2 coated | 50 |
| 7 | HR-2 coated | 60 |
| 8 | Vansil ® HR-325 | 20 |
| | Wollastonite | |
| | (R. T. Vanderbilt Co., | |
| | Norwalk, CT, USA) | |
| 9 | Vansil ® HR-325 | 40 |
| | Wollastonite | |
| 10 | Vansil ® HR-325AS | 20 |
| | (aminosilane treated) | |
| | wollastonite | |
| 11 | Vansil ® HR-325AS | 40 |
| | wollastonite | |
| 12 | Flextalc 1222 talc | 20 |
| | (Kish Co.) | |
| 13 | Flextalc 1222 talc | 40 |
| 14 | Suzorite 400 HK mica | 20 |
| | (Zemex Industrial | |
| | Minerals, Atlanta, GA, | |
| | USA) | |

All the polyimide films prepared in Examples 1-14 from the same base polymer backbone were characterized by several analytical methods and these are summarized in Table 2. Dynamic Mechanical Analysis (DMA) was carried out on a TA Instruments DMA-2980. Samples were heated at 5° C./min from room temperature to 350° C., then cooled and reheated in a second scan to 500° C. In some cases, the samples were only heated once to 500° C. This is noted in Table 2. Storage moduli are evaluated at 50 and 480° C. (or lower, as noted, if the signal integrity was lost at temperature above Tg, eg. sample became too soft). Glass transition temperatures were recorded as the peak of the tan delta curve during the 2^{nd} scan to 500° C.

Coefficient of thermal expansion (CTE) measurements were carried out on a TA Instruments TMA-2940 Thermal Mechanical Analyzer (TMA). Samples are heated from room temperature to 380° C. at 10° C./min during a first scan and then cooled to room temperature and reheated in a second scan at 10° C./min to 380° C. The values were analyzed from 50-350° C. and reported in ppm/° C. from the second heating scan.

Thermal Gravimetric Analysis (TGA) was carried out on a TA Instruments TGA-2050. Samples were heated under nitrogen at 20° C./min from room temperature to 500° C. and then held at 500° C. for 30 min. The weight loss from the beginning to the end of the isothermal hold at 500° C. is taken as a percentage of the initial sample weight.

TABLE 2

| | Storage | | | | |
|---|---|---|---|---|---|
| | Modulus | Storage | | | |
| | (DMA) | Modulus | Tg, | | TGA, |
| | at 50° C., | (DMA) at | ° C. | | % wt |
| | GPa, | 480° C. (or | 2^{nd} | CTE, | loss at |
| | 1^{st} heat | noted temp.), | DMA | ppm/° C. | 500° C., |
| Example # | (2^{nd} heat) | MPa. 2^{nd} heat | heat | 50-350 C. | 30 min |
| 1 | 8.8 (9.7) | 85 (400° C.) | 360 | 28 | 0.6 |
| 2 | 12.0 (12.6) | 230 | 361 | 23 | 0.5 |
| 3 | 19.9 (20.8) | 1060 | 351 | 22 | 0.6 |
| 4 | 13.0 (13.4) | 190 | 356 | 22 | 0.5 |
| 5 | 15.1 (17.3) | 600 | 359 | 22 | 0.4 |
| 6 | 15.2* | 840* | — | 21 | 0.6 |
| 7 | 15.8* | 1500* | — | 19 | 0.5 |
| 8 | 9.4 (11.0) | 240 | 356 | 24 | 0.6 |
| 9 | 13.9 (15.0) | 910 | 359 | 24 | 0.7 |
| 10 | 8.0 (10.1) | 130 (413° C.) | 357 | 19 | 0.6 |
| 11 | 14.4 (14.7) | 550 | 356 | 47 (19)** | 0.7 |
| 12 | 7.7 (10.1) | 150 (384° C.) | 354 | 20 | 0.4 |
| 13 | 12.5 (13.6) | 260 | 352 | 21 | 0.5 |
| 14 | 13.9* | 500 | — | 19 | 0.5 |

*single heating scan only - room temperature to 500° C.
**separate runs on two different film samples, reason for high CTE value on first sample is unknown.

The results indicate that the modulus at room temperature and particularly at temperatures above the Tg is significantly higher for the filled films compared to unfilled Example 1. CTE over the 50-350° C. temperature range is also somewhat lower for the filled materials in almost all samples.

### Example 15

Example 15 illustrates the use of a polyimide coated stainless steel foil. A random polyamic acid copolymer of PMDA/BPDA//PPD/ODA of about a 60/40//60/40 molar ratio was prepared by standard methods in DMAC at about 18% solids to a viscosity of about 500 poise. This polymer solution was subsequently continuously coated onto a 20 um thick, about 30.8 cm wide, stainless steel foil roll (SUS304H-TA MW, Nippon Steel Corporation, Japan) and dried in a continuous drying oven from about 88° C. to a final zone temperature of approximately 160° C. to give a tack free coating on the finished side of the foil. The coated roll was unwound/rewound to give a loosely wrapped roll, then placed in an nitrogen purged oven and ramped from ambient temperature to about 200° C. over 30 min, held there for 30 min, then ramped to 350° C. over 30 min and held there for 1 hour in order to cure to polyimide. The coated roll was then slow cooled over several hours to room temperature under a nitrogen purge. The resulting stainless steel roll coated with about an 8 micron thick polyimide coating exhibited very little curl and thus resulted in a thermally stable, flexible substrate suitable for CIGS photovoltaic use. The surface roughness of the uncoated stainless steel foil (on the side to be coated) was measured on a Wyco NT1000 profilometer with Wyco Vision 32 software and gave a Ra value of 209 nm. The same side overcoated with the polyimide exhibited a Ra value of 74 nm indicating the smoothing effect of the polyimide coating on the surface. Thermal Gravimetric Analysis (TGA) was carried out on a TA Instruments TGA-2050. Samples were heated under nitrogen at 20° C./min from room temperature to 500° C. and then held at 500° C. for 30 min. The weight loss from the beginning to the end of the isothermal hold at 500° C. was taken as a percentage of the initial sample weight. TGA analysis of the polyimide coated stainless steel, showed a weight loss at 500° C. of about 0.06% over 30 min.

### Example 16

In a similar manner to Example 15, filled polyamic acids such as those described in Examples 2 through 14 could be coated onto stainless steel and other metal foils to give filled polyimide coatings on metal foil that should be suitable for use as flexible substrates for CIGS photovoltaic devices. Depending on the particular filled polymer solution to be coated, some adjustment of process parameters (solution viscosity, coating conditions, drying temperatures, curing conditions) may be necessary in order to optimize coating quality and product performance. Such process adjustments are known to those skilled in the art and ordinary skill and experimentation may be required to optimize performance for any particular material.

Examples 17 through 19 indicate the potential benefits of some fillers on the adhesion properties of polyimides to a stainless steel foil, where the stainless steel foil bonding surface is not specially treated or prepared to promote bonding.

### Example 17

### Polyimide (BDPA/PPD) Comprising (10 vol % SiO₂) Filler on Stainless Steel

About 165.12 grams of about 17.5 wt % BPDA:PPD (0.98:1 stoichiometry, BPDA:PDA) prepolymer solution in dimethylacetamide (DMAC) was added to a 250 ml, three neck round bottom flask and was purged with nitrogen gas.

In a separate container, about 13.064 grams of nanosilica in DMAC (DMAC-ST, 20.5 wt % as SiO₂ in DMAC, Nissan Chemicals, USA), which had been stored over molecular sieves (zeolite, type 3A), and about 0.194 grams of PMDA (pyromellitic anhydride, Aldrich Chemicals) was added.

The mixture of the nanosilicon oxide colloid and the PMDA was allowed to stir for 1 hour under flowing nitrogen gas.

The nanocolloid, containing PMDA, was then combined with the BPDA:PPD prepolymer in the round bottom flask, and allowed to stir for four hours.

After filtering the mixture of nanocolloid and prepolymer through 45 micron filter media (Millipore, 45 micron polypropylene screen, PP4504700), 84.3 grams for of this mixture was transferred into a smaller container.

In a separate container, a 6 wt % solution of pyromellitic anhydride (PMDA) was prepared by combining 0.9 g of PMDA (Aldrich 412287, Allentown, PA) and 15 ml of DMAC.

The PMDA solution was slowly added to the prepolymer slurry, with stirring, to achieve a final viscosity of 1100 poise. The formulation was stored overnight at 0° C. to allow it to degas.

The formulation was cast using a 15 mil doctor blade onto a surface onto a 4″×8″ piece of 0418 stainless steel foil. The foil coated with prepolymer was allowed to dry on a hot plate at 80° C. for 20 minutes.

After further drying at room temperature under vacuum for 12 hours, the coated foil was placed in a furnace (Thermolyne, F6000 box furnace). The furnace was heated according to the following temperature protocol in flowing nitrogen gas:
40° C. to 125° C. (ramp at 4° C./min)
125° C. to 125° C. (30 min)
125° C. to 350° C. (ramp at 4° C./min)
350° C. to 350° C. (isotherm, 30 min)
350° C. to 450° C. (ramp at 5° C./min)
450° C. to 450° C. (isotherm, 20 min)
450° C. to 40° C. (cooling at 8° C./min)

The film was visually defect free, with no evidence of blistering or macroscopic bubbling. Hence nanoscopic colloidal oxide filler appears to aid adhesion between the (filled) polyimide and the metal substrate.

### Example 18

### BPDA/PPD on Stainless Steel

A 17.5 wt % BPDA:PPD prepolymer solution in DMAC (0.98:1 stoichiometry, BPDA:PDA) was used. 6 wt % PMDA solution (in DMAC) was slowly added to the prepolymer to achieve a final viscosity of 500 poise. The formulation was stored overnight at 0° C. to allow it to degas.

The formulation was cast using a 15 mil doctor blade onto a surface onto a 4×3″ piece of 0418 stainless steel foil. The foil coated with prepolymer was allowed to dry on a hot plate at 80° C. for 20 minutes.

After further drying at room temperature under vacuum for 12 hours, the coated foil was placed in a furnace (Thermolyne, F6000 box furnace). The furnace heated according to the following temperature protocol in flowing nitrogen gas:
40° C. to 125° C. (ramp at 4° C./min)
125° C. to 125° C. (30 min)
125° C. to 350° C. (ramp at 4° C./min)
350° C. to 350° C. (isotherm, 30 min)
350° C. to 450° C. (ramp at 5° C./min)
450° C. to 450° C. (isotherm, 20 min)
450° C. to 40° C. (cooling at 8° C./min)

The final coating of the polyimide on the steel foil had coating defects, such as blisters and bubbles (some measurement >1 mm in diameter), indicating that an unfilled polyimide tends to be more difficult to adhere to a metal substrate and will generally require a higher level of metal surface preparation, including perhaps an adhesion primer or other surface treatment to promote bonding between the polyimide and the metal.

### Example 19

### BPDA:PPD with about 14.64 volume % TiO₂

191.9 g of DMAC was combined with 33.99 g of TiO₂ (FTL-110, acicular TiO₂, Ishihara Corporation, USA). This slurry was blended using a high-shear mixer (Silverson Model L4RT high-shear mixer, Silverson Machines, LTD, Chesham Baucks, England) equipped with a square-hole, high-shear screen. The material was mixed, with a blade, at a speed of approximately 4000 rpm for approximately 10 minutes.

69.335 g of this slurry was combined with 129.253 g of BPDA/PPD prepolymer (17.5 wt % in DMAC) in a 250 ml, 3-neck, round-bottom flask. The mixture was slowly agitated with a paddle stirrer overnight under a slow nitrogen gas purge. The material was then blended with the high-shear mixer a second time (approximately 10 min, 4000 rpm) and the filtered through 45 micron filter media (Millipore, 45 micron polypropylene, PP4504700).

A 6 wt % PMDA solution (in DMAC) was slowly added to the prepolymer to achieve a final viscosity of approximately 1800 poise. The formulation was stored overnight at 0° C. to allow it to degas.

The formulation was cast using a 15 mil doctor blade onto a surface onto a 4×3″ piece of 0418 stainless steel foil. The foil coated with prepolymer was allowed to dry on a hot plate at 80° C. for 20 minutes.

After further drying at room temperature under vacuum for 12 hours, the coated foil was placed in a furnace (Thermolyne, F6000 box furnace). The furnace was heated according to the following temperature protocol under flowing nitrogen:
40° C. to 125° C. (ramp at 4° C./min)
125° C. to 125° C. (30 min)
125° C. to 350° C. (ramp at 4° C./min)
350° C. to 350° C. (isotherm, 30 min)
350° C. to 450° C. (ramp at 5° C./min)
450° C. to 450° C. (isotherm, 20 min)
450° C. to 40° C. (cooling at 8° C./min)

The final coating of the polyimide on the steel foil was non-uniform, and there was extensive evidence of the polyimide film delaminating from the steel substrate. This would indicate that nanoscopic colloidal oxide as a polyimide filler promotes adhesion to metal more readily (see Example 17) than unfilled polyimide (see Example 18) or acicular oxide (this Example 19) which is nanoscopic in at least one dimension but has a much higher aspect ratio than the colloidal oxide filler of Example 17. However, Example 15 does illustrate an unfilled polyimide having excellent adhesion to a metal substrate, where Example 15 uses a particular stainless steel advertised as having a suitable (presumably, proprietary) surface for bonding (Nippon Steel, SUS304H-TA MW). Hence, colloidal nano-silica filler does seem to improve adhesion to metal, but adhesion to metal can be accomplished also in other ways, such as, by special cleaning, using adhesion primers or other surface treatments that aid in the bonding of polyimide to metal.

Note that not all of the activities described above in the general description or the examples are required, that a portion of a specific activity may not be required, and that further activities may be performed in addition to those described. Still further, the order in which each of the activities are listed are not necessarily the order in which they are performed. After reading this specification, skilled artisans will be capable of determining what activities can be used for their specific needs or desires.

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense and all such modifications are intended to be included within the scope of the invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

When an amount, concentration, or other value or parameter is given as either a range, preferred range or a list of upper values and lower values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

What is claimed is:

1. A CIGS laminate structure comprising:
a) a metal foil having a thickness from 5 to 100 microns,
b) a polyimide dielectric layer having a top surface and a bottom surface, the bottom surface being in direct contact with a surface of the metal foil, the polyimide dielectric layer having a thickness from 8 to 100 microns and comprising a polyimide derived from at least one aromatic rigid rod diamine and at least one aromatic rigid rod dianhydride to provide a polyimide having a Tg greater than 300° C. and to provide a polyimide layer having an isothermal weight loss of less than 1% under inert conditions at 500° C. over 30 minutes and an in-plane CTE less than 25 ppm/° C.,
c) a bottom electrode formed directly on the polyimide dielectric layer top surface, whereby the polyimide layer is between the metal foil and the bottom electrode, and
d) a CIGS layer formed directly on the bottom electrode, whereby the bottom electrode is between the CIGS layer and the polyimide dielectric layer.

2. A CIGS laminate structure in accordance with claim 1, wherein the bottom electrode comprises molybdenum, and wherein the laminate supports a plurality of CIGS photovoltaic cells that are monolithically integrated into a photovoltaic module.

3. A CIGS laminate structure in accordance with claim 1 wherein the polyimide has a Tg greater than 320° C. and the polyimide layer has an in-plane CTE less than 20 ppm/° C. and a dielectric strength greater than 39.4 KV/mm, and wherein the bottom electrode is applied in a reel-to-reel process.

4. A CIGS laminate structure in accordance with claim 1 wherein the polyimide layer has a Tg greater than 320° C. and an in-plane CTE less than 10 ppm/° C.

5. A CIGS laminate structure in accordance with claim 1, wherein the metal foil comprises stainless steel.

6. A CIGS laminate structure in accordance with claim 1, wherein:
a) the aromatic rigid rod diamine is selected from a group consisting of 1,4-diaminobenzene (PPD), 4,4′-diaminobiphenyl, 2,2′-bis(trifluoromethyl)benzidene (TFMB), 1,4-naphthalenediamine, 1,5-naphthalenediamine and mixtures thereof; and
b) the aromatic rigid rod dianhydride is selected from a group consisting of pyromellitic dianhydride (PMDA), 3,3′,4,4′-biphenyl tetracarboxylic dianhydride (BPDA), and mixtures thereof.

7. A CIGS laminate structure in accordance with claim 1, wherein the polyimide is derived from 1,4-diaminobenzene (PPD) and 3,3′,4,4′-biphenyl tetracarboxylic dianhydride (BPDA).

8. A CIGS laminate structure in accordance with claim 1, wherein the polyimide is derived from 3,3′,4,4′-biphenyl tetracarboxylic dianhydride (BPDA) and a combination of 1,4-diaminobenzene (PPD) and 1,5-naphthalenediamine, where over 50 mole percent of the diamine is 1,5-naphthalenediamine.

9. A CIGS laminate structure in accordance with claim 1, wherein the polyimide dielectric layer comprises an average surface roughness of less than 500 nm prior to forming the bottom electrode upon said polyimide surface.

10. A CIGS laminate structure in accordance with claim 1, wherein the polyimide dielectric layer further comprises a filler present in an amount from 10 to 70 weight percent of the total weight of the polyimide dielectric layer, wherein the filler is selected from a group consisting of oxides, nitrides, carbides and combinations thereof.

11. A CIGS laminate structure in accordance with claim 1, wherein the polyimide dielectric layer further comprises a filler, the filler is on average less than a micron in at least one dimension, and the filler is selected from a group consisting of platelet-shaped fillers, needle-like fillers, fibrous fillers and mixtures thereof.

12. A CIGS laminate structure in accordance with claim 1, wherein the polyimide dielectric layer further comprises a filler, and the filler is selected from a group consisting of mica, talc, boron nitride, wollastonite, clays, calcinated clays, silica, alumina, platelet alumina, glass flake, glass fiber and mixtures thereof.

13. A CIGS laminate structure in accordance with claim 1, wherein the polyimide dielectric layer further comprises a thermally stable reinforcing fabric, inorganic paper, sheet, scrim and combinations thereof.

14. A CIGS laminate structure in accordance with claim 1, wherein the polyimide dielectric layer comprises two or more layers.

15. A CIGS laminate structure in accordance with claim 1, wherein the polyimide dielectric layer comprises a filler having at least one dimension that on average is less than 1000 nm, and the filler comprises oxygen and at least one member of the group consisting of aluminum, silicon, titanium, magnesium and combinations thereof.

16. A CIGS laminate structure in accordance with claim 1, wherein the metal foil comprises titanium.

17. A CIGS laminate structure in accordance with claim 1, wherein the polyimide dielectric layer comprises a filler: i. having an aspect ratio less than 3:1; ii. having a size that is less than 1000 nm in all dimensions; and comprising oxygen and at least one member of the group consisting of aluminum, silicon, titanium, magnesium and combinations thereof.

18. A CIGS laminate structure comprising:
a) a metal foil having a thickness from 5 to 100 microns,
b) a polyimide dielectric layer having a top surface and a bottom surface, the bottom surface being in direct contact with a surface of the metal foil, the polyimide dielectric layer having a thickness from 8 to 100 microns and comprising a polyimide derived from: i. an aromatic diahydride, the aromatic dianhydride being an aromatic rigid rod dianhydride and optionally, an aromatic non rigid rod dianhydride, where at least 50 mole percent of the aromatic dianhydride is an aromatic rigid rod dianhydride and the remainder, if any, is an aromatic non rigid rod dianhydride; and ii. an aromatic diamine, the aromatic diamine being an aromatic rigid rod diamine and optionally, an aromatic non rigid rod diamine, where at least 50 mole percent of the aromatic diamine is an aromatic rigid rod diamine and the remainder, if any, is an aromatic non rigid rod diamine, wherein:
i) the aromatic rigid rod diamine is selected from a group consisting of 1,4-diaminobenzene (PPD), 4,4′-diaminobiphenyl, 2,2′-bis(trifluoromethyl)benzidene (TFMB), 1,4-naphthalenediamine, 1,5-naphthalenediamine and mixtures thereof;
ii.) the non rigid rod aromatic diamine is selected from a group consisting of 3,4′-diaminodiphenyl ether (3,4′-ODA), 4,4′-diaminodiphenyl ether (4,4′-ODA), 1,3-diaminobenzene (MPD), 4,4′-diaminodiphenyl sulfide, 9,9′-bis(4-amino)fluorene, and mixtures there;
iii) the aromatic rigid rod dianhydride is selected from a group consisting of pyromellitic dianhydride (PMDA), 3,3′,4,4′-biphenyl tetracarboxylic dianhydride (BPDA), and mixtures thereof; and
iv) the non rigid rod aromatic dianhydride is selected from a group consisting of: 3,3′,4,4′-benzophenone tetracarboxylic dianhydride (BTDA); 4,4′-oxydiphthalic anhydride (ODPA), 3,3′,4,4′-diphenyl sulfone tetracarboxylic dianhydride (DSDA), 2,2-bis(3,4-dicarboxyphenyl)hexafluoropropane dianhydride (6FDA) and mixtures thereof,
to provide a polyimide having a Tg greater than 300° C. and to provide a polyimide layer having an isothermal weight loss of less than 1% under inert conditions at 500° C. over 30 minutes and an in-plane CTE less than 25 ppm/° C.,
c) a bottom electrode formed directly on the polyimide dielectric layer top surface, whereby the polyimide layer is between the metal foil and the bottom electrode, and
d) a CIGS layer formed directly on the bottom electrode, whereby the bottom electrode is between the CIGS layer and the polyimide dielectric layer.

19. A CIGS laminate structure in accordance with claim 1, wherein the polyimide dielectric layer further comprises a filler, where the filler is selected from a group consisting of oxides, nitrides, carbides and combinations thereof, and the filler averages less than 200 nm in at least one dimension.
